(19) United States
(12) Patent Application Publication
(10) Pub. No.: US 2014/0174710 A1
(43) Pub. Date: Jun. 26, 2014

(54) WATER-COOLING RADIATOR

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: QIANG GUO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/092,905

(22) Filed: Nov. 27, 2013

(30) Foreign Application Priority Data
Dec. 25, 2012 (CN) 2012105693661

(51) Int. Cl. H05K 7/20; F01P 7/00

(52) U.S. Cl. CPC H05K 7/20281; F01P 7/00
USPC 165/244

(57) ABSTRACT

A water-cooling radiator includes a cooling module, a control circuit, a temperature sensor, and a display. The temperature sensor is used to sense an instant temperature of a heat generating device and output the instant temperature to the control circuit. The control circuit outputs a voltage for the cooling module corresponding to the instant temperature received from the temperature sensor. The control circuit compares the instant temperature with a preset temperature. When the instant temperature is higher than the preset temperature, the control circuit increases the voltage outputted to the cooling module to reduce the instant temperature of the heat generating device. When the instant temperature is lower than the preset temperature, the control circuit reduces the voltage outputted to the cooling module.

### BACKGROUND

1. Technical Field

The present disclosure relates to a water-cooling radiator.

2. Description of Related Art

A typical water-cooling radiator includes a water-cooling unit, circulating water, a pump, a number of pipes, and a water tank. The water-cooling unit, usually made of metal, is used to contact a heat generating device to absorb heat. The water flowing in the pipe takes heat away from the water-cooling unit. However, the typical water-cooling radiator cannot sense or control an instant temperature of the heat generating device.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a water-cooling radiator of the present disclosure, wherein the water-cooling radiator includes a control circuit.

FIG. 2 is a block diagram of the control circuit of FIG. 1.

### DETAILED DESCRIPTION

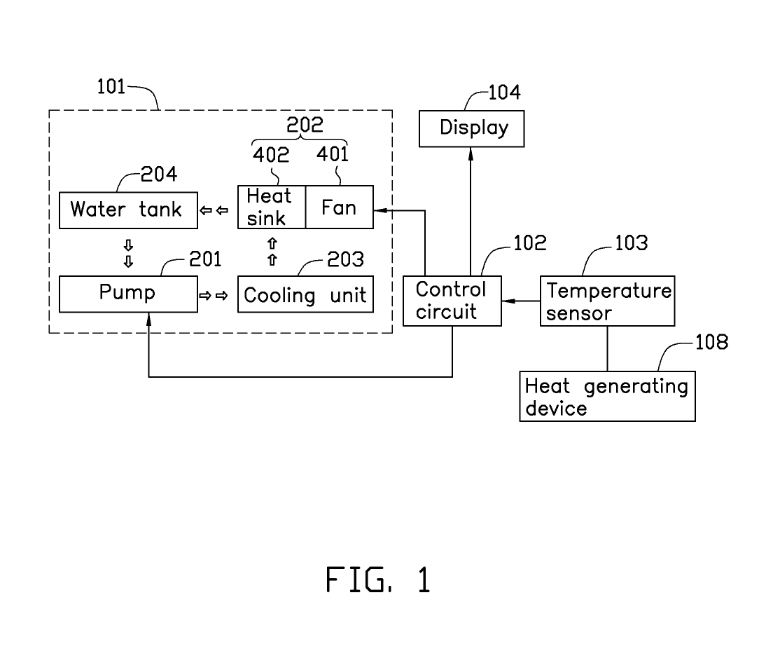

FIG. 1 shows an embodiment of a water-cooling radiator of the present disclosure.

The water-cooling radiator 10 includes a cooling module 101, a control circuit 102, a temperature sensor 103, and a display 104. The cooling module 101 includes a pump 201, a heat dissipation unit 202, a water-cooling unit 203, and a water tank 204 all connected end to end with pipes. The pump 201 and the heat dissipation unit 202 are connected to the control circuit 102.

The pump 201 pumps water to flow in the pipes. The water-cooling unit 203 is made of metal and has an inside channel through which the water flows. The water-cooling unit 203 contacts a heat generating device 108 to absorb heat from the heat generating device 108. The water flowing in the pipe takes heat in the water-cooling unit 203 away.

The heat dissipation unit 202 includes a plurality of fans 401 and a plurality of heat sinks 402. The heat sinks 402 define a plurality of channels communicating with the inside channel of the water-cooling unit 203. The water from the water-cooling unit 203 flows to the heat sinks 402 and carries heat to the heat sinks 402. The fans 401 are set near the heat sinks 402 to dissipate heat for the heat sinks 402, to reduce temperature of the water. The channels of the heat sinks 402 are also communicated with the water tank 204 through a pipe. The water is finally recycled to the water tank 204.

The temperature sensor 103 is used to sense an instant temperature of the heat generating device 108 and output the instant temperature to the control circuit 102.

The control circuit 102 outputs a duty ratio of a voltage for the cooling module 101 corresponding to the instant temperature received from the temperature sensor 103. The control circuit 102 compares the instant temperature with a preset temperature stored in the control circuit 102. When the instant temperature is higher than the preset temperature, the control circuit 102 increases the duty ratio of the voltage outputted to the pump 201 and fans 401 in the cooling module 101 to increase the speeds of the pump 201 and the fans 401, thereby reducing the instant temperature of the heat generating device 108. When the instant temperature is lower than the preset temperature, the control circuit 102 decreases the duty ratio of the voltage outputted to the pump 201 and fans 401 in the cooling module 101 to decrease the speeds of the pump 201 and the fans 401, thereby reducing energy cost. When the instant temperature is equal to the preset temperature, the control circuit 102 maintains the duty ratio of the voltage outputted to the pump 201 and the fans 401 to keep the speeds of the pump 201 and the fans 401, thereby keeping the instant temperature of the heat generating device 108.

The display 104 is connected to the control circuit 102 to display the instant temperature of the heat generating device 108 and the preset temperature.

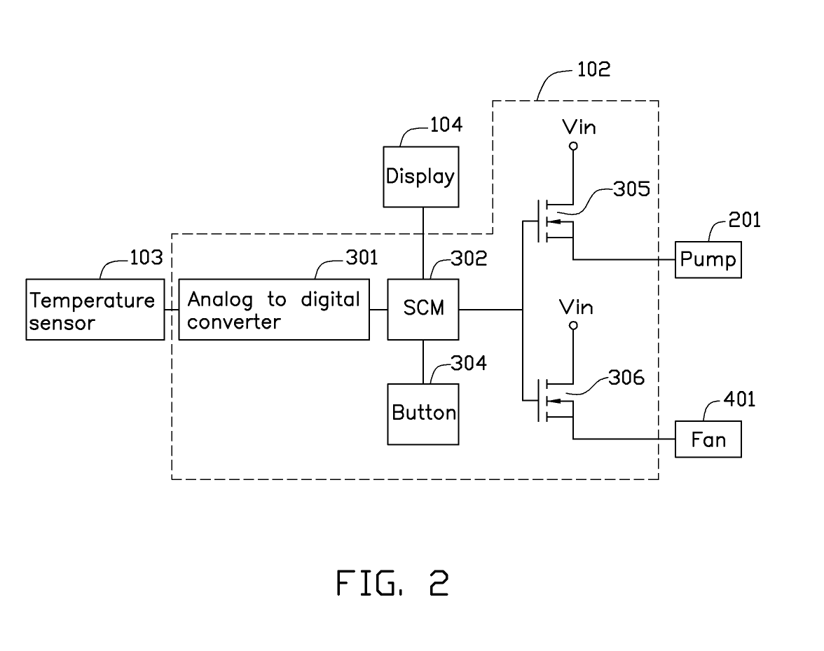

FIG. 2 shows an embodiment of the control circuit 102 of the water-cooling radiator 10.

The control circuit 102 includes an analog to digital (A/D) converter 301, a single chip microcontroller (SCM) 302, a button 304, two metallic oxide semiconductor field effect transistors (MOSFETs) 305 and 306, and a power source Vin.

Drains of the MOSFETs 305 and 306 are connected to the power source Vin. Gates of the MOSFETs 305 and 306 are connected to the SCM 302 to receive pulse control signals. A source of the MOSFET 305 is connected to the pump 201. A source of the MOSFET 306 is connected to the fans 401. In the embodiment, the MOSFETs are n-channel MOSFETs. When the SCM 302 outputs a high level signal, such as logic 1, the MOSFETs 305 and 306 are turned on, and the power source Vin supplies power for the pump 201 and the fans 401. When the SCM 302 outputs a low level signal, such as logic 0, the MOSFETs 305 and 306 are turned off, and the power source Vin does not supply power for the pump 201 and the fans 401. Because the SCM 302 outputs pulse control signals, the MOSFETs 305 and 306 are alternately turned on and off

The button 304 is used to set a value of the preset temperature. The temperature sensor 103 outputs an analog signal corresponding to the instant temperature to the A/D converter 301, and the A/D converter 301 converts the analog signal to a digital signal and outputs the digital signal to the SCM 302. The SCM 302 outputs the digital signal to the display 104. The display 104 displays the value of the instant temperature. The SCM 302 compares the value of the instant temperature with the preset temperature and outputs control signals corresponding to results of the comparation. When the instant temperature is higher than the preset temperature, the SCM 302 increases a duty ratio of the pulse control signal to increase the time of the power source Vin supplying power for the pump 201 and the fans 401 in a cycle, thereby increasing the voltage outputted to the pump 201 and fans 401. The higher the voltage of the pump 201 is, the faster the water flows. The higher the voltage of the fans 401, the higher a rotation speed of the fans 401. When the instant temperature is lower than the preset temperature, the SCM 302 decreases the duty ratio of the pulse control signal to reduce the time of the power source Vin supplying power for the pump 201 and the fans 401 in a cycle, thereby decreasing the voltage outputted to the pump 201 and fans 401. When the instant temperature is equal to the preset temperature, the control circuit 102 keeps the value of the voltage outputted to the pump 201 and the fans 401 to keep the instant temperature of the heat generating device 108.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A water-cooling radiator, comprising:
a cooling module that cools a heat generating device;
a temperature sensor that senses an instant temperature of the heat generating device;
a control circuit connected to the cooling module and the temperature sensor, wherein the control circuit receives a signal about the instant temperature of the heat generating device from the temperature sensor and compares the instant temperature with a preset temperature; when the instant temperature is higher than the preset temperature, the control circuit increases a duty ratio of a voltage outputted to the cooling module, and when the instant temperature is lower than the preset temperature, the control circuit decreases the duty ratio of the voltage outputted to the cooling module.

2. The water-cooling radiator of claim 1, further comprising a display connected to the control circuit to display the instant temperature of the heat generating device.

3. The water-cooling radiator of claim 2, wherein the control circuit comprises a signal chip microcontroller (SCM), an analog to digital (A/D) converter, a first metallic oxide semiconductor field effect tube (MOSFET), a second MOSFET, and a power source, the SCM is connected to the temperature sensor through the A/D converter, the A/D converter is used to convert an analog signal of the instant temperature of the heat generating device from the temperature sensor into a digital signal and output the digital signal to the SCM, the SCM compares the instant temperature with the preset temperature and outputs control signals corresponding to results of the comparation, an output of the SCM is connected to gates of the first MOSFET and the second MOSFET, drains of the first MOSFET and the second MOSFET are connected to the power source, sources of the first and second MOSFETs are connected to the cooling module.

4. The water-cooling radiator of claim 3, wherein the cooling module comprises a pump and a plurality of fans, wherein the source of the first MOSFET is connected to the pump, and the source of the second MOSFET is connected to the plurality of fans.

5. The water-cooling radiator of claim 4, wherein the cooling module further comprises a water tank, a cooling unit, and a plurality of heat sink, wherein the water tank, the pump, the cooling unit, and the plurality of heat sinks are connected end to end, the plurality of fans is attached to the plurality of heat sinks.

6. The water-cooling radiator of claim 3, wherein the control circuit further comprises a button to set the preset temperature.
